(19) United States
(12) Patent Application Publication
(10) Pub. No.: US 2015/0028300 A1
(43) Pub. Date: Jan. 29, 2015

(54) THIN FILM TRANSISTOR, ORGANIC LIGHT-EMITTING DISPLAY APPARATUS INCLUDING THE SAME, AND METHOD OF MANUFACTURING THE THIN FILM TRANSISTOR

(71) Applicant: Samsung Display Co., Ltd., Yongin-City (KR)

(72) Inventors: Kwang-Suk KIM, Yongin-City (KR); Jong-Han Jeong, Yongin-City (KR); Yeon-Gon Mo, Yongin-City (KR)

(73) Assignee: Samsung Display Co., Ltd., Yongin-City (KR)

(21) Appl. No.: 14/255,786

(22) Filed: Apr. 17, 2014

(30) Foreign Application Priority Data
Jul. 23, 2013 (KR) 10-2013-0086975

(51) Int. Cl. H01L 29/786; H01L 29/66; H01L 27/32

(52) U.S. Cl. CPC H01L 29/7869; H01L 27/3248; H01L 29/66969
USPC 257/40; 257/43; 438/104

(57) ABSTRACT

A thin film transistor includes a gate electrode provided on a substrate, a semiconductor layer insulated from the gate electrode and including indium, tin, zinc and gallium oxide, and source/drain electrodes formed on the semiconductor layer.

### RELATED APPLICATIONS

This application claims the benefit of Korean Patent Application No. 10-2013-0086975, filed on Jul. 23, 2013, in the Korean Intellectual Property Office, the disclosure of which is incorporated herein in its entirety by reference.

### BACKGROUND

1. Field

One or more embodiments of the present invention relate to a thin film transistor including an oxide semiconductor, an organic light-emitting display apparatus including the same, and a method of manufacturing the thin film transistor.

2. Description of the Related Art

A flat panel display apparatus such as an organic light-emitting display apparatus, a liquid crystal display apparatus, etc. is manufactured on a substrate including patterns having at least one thin film transistor for driving a pixel, a capacitor, and wirings for connecting the components. The thin film transistor includes an active layer providing a channel region, a source region and a drain region, and a gate electrode formed on the channel region and electrically insulated from the active layer by a gate insulating layer.

The active layer of the thin film transistor having the above-described structure may be commonly formed by using a semiconductor material such as amorphous silicon or polysilicon. When the active layer is formed by using the amorphous silicon, carrier mobility may be low, and it may be difficult to obtain a driving circuit having a rapid operation speed. When the active layer is formed by using the polysilicon, the mobility may be high. However a threshold voltage of the thin film transistor may be non-uniform. Thus, an additional compensating circuit may be necessary to compensate for the non-uniform threshold voltage. In addition, since a common method of forming thin film transistor by using a low temperature polysilicon (LTPS) involves an expensive process such as laser heat treatment, equipment and management costs are high, and it may be difficult to use the method to a large-sized panel. To solve the above-described problems, research on using an oxide semiconductor in an active layer of the thin film transistor is being conducted.

When the oxide semiconductor is used in a thin film transistor as an active layer, mobility of the thin film transistor and the reliability of materials are in a trade-off relationship. High mobility of about 30 cm²/V·sec may be necessary to manufacture a high resolution display apparatus. When an oxide semiconductor material having such a high mobility is used as an active layer, the reliability of the material may be poor, and a device may be easily deteriorated.

### SUMMARY

One or more embodiments of the present invention considering the above-described defects include a thin film transistor including an oxide semiconductor having a high mobility and a high reliability of materials, an organic light-emitting display apparatus including the same, and a method of manufacturing the thin film transistor. However, the object is an exemplary embodiment, and the scope of the present invention is not limited thereto.

Additional aspects will be set forth in part in the description which follows and, in part, will be apparent from the description, or may be learned by practice of the presented embodiments.

According to one or more embodiments of the present invention, a thin film transistor includes a gate electrode provided on a substrate, a semiconductor layer insulated from the gate electrode, and including gallium, indium, tin and zinc gallium oxides (GITZO) and source/drain electrodes formed on the semiconductor layer.

An amount of the gallium may be from about 5 atom % to about 25 atom % of the semiconductor layer.

An amount of indium (In) may be from about 10 atom % to about 40 atom % of the semiconductor layer.

The thin film transistor may further include a gate insulating layer interposed between the gate electrode and the semiconductor layer and making contact with the gate electrode and the semiconductor layer, and an etch stopping layer interposed between the semiconductor layer and the source/drain electrodes and making contact with the semiconductor layer and the source/drain electrodes. The gate insulating layer and the etch stopping layer may include silicon oxide (SiOx).

According to one or more embodiments of the present invention, an organic light-emitting display apparatus includes a thin film transistor including a gate electrode provided on a substrate, a semiconductor layer insulated from the gate electrode, and including gallium, indium, tin and zinc oxides (GITZO), and source/drain electrodes formed on the semiconductor layer; a passivation layer covering the thin film transistor; and an organic light-emitting device provided on the passivation layer and including a first electrode, an intermediate layer and a second electrode.

According to one or more embodiments of the present invention, a method of manufacturing a thin film transistor includes depositing a gate electrode material on a substrate and patterning to form a gate electrode, depositing a semiconductor material on the gate electrode using a single target including gallium, indium, tin and zinc oxide (GITZO) to be insulated from the gate electrode and patterning the semiconductor material to form a semiconductor layer, and depositing source/drain materials on the semiconductor layer and patterning to form source/drain electrodes to make a contact with the semiconductor layer through a contact hole.

An amount of the gallium may be from about 5 atom % to about 25 atom % of the semiconductor layer.

An amount of indium (In) may be from about 10 atom % to about 40 atom % of the semiconductor layer.

The method may further include forming a gate insulating layer to cover the gate electrode, and depositing an etch stopping material to cover the semiconductor layer and patterning to form the contact hole. The gate insulating layer and the etch stopping layer may include silicon oxide (SiOx).

According to an exemplary embodiment of the present invention, a thin film transistor including an oxide semiconductor improving both of the mobility and the reliability of materials, an organic light-emitting display apparatus including the same, and a method of manufacturing the thin film transistor may be accomplished. Of course, the scope of the present invention is not limited to the effects.

### BRIEF DESCRIPTION OF THE DRAWINGS

These and/or other aspects will become apparent and more readily appreciated from the following description of the embodiments, taken in conjunction with the accompanying drawings in which:

FIG. 1 is a cross-sectional view schematically illustrating an organic light-emitting display apparatus including a thin film transistor in accordance with an exemplary embodiment of the present invention;

FIG. 2 is a graph illustrating carrier properties according to the concentration of indium (atom %) included in a semiconductor layer;

FIGS. 3, 4, 5 and 6 are graphs illustrating drain current intensity according to gate voltage in a thin film transistor to show properties of a transistor; and

FIGS. 7 and 8 are graphs illustrating carrier properties according to the concentration of gallium (atom %) included in a semiconductor layer.

### DETAILED DESCRIPTION

Hereinafter, embodiments of the inventive concept will be described in detail with reference to the accompanying drawings. Like reference numerals refer to the like elements throughout the specification. The present embodiments may have different forms and should not be construed as being limited to the descriptions set forth herein. Expressions such as “at least one of,” when preceding a list of elements, modify the entire list of elements and do not modify the individual elements of the list.

Referring to the drawings, the same or corresponding elements will be given the same reference symbols, and duplicated explanation thereon will be omitted.

As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, elements, and/or components, but do not preclude the presence or addition of one or more other features, elements, and/or components. It will be understood that when a layer, a region or an element is referred to as being “on” another layer, region, or element, it can be directly on the other layer, region or element, or formed with intervening layer, region or elements.

For convenience of explanation, the size of elements in the drawings may be exaggerated or reduced. For example, the size and the thickness of each element in the drawings are optional, and the present invention will not be limited thereto.

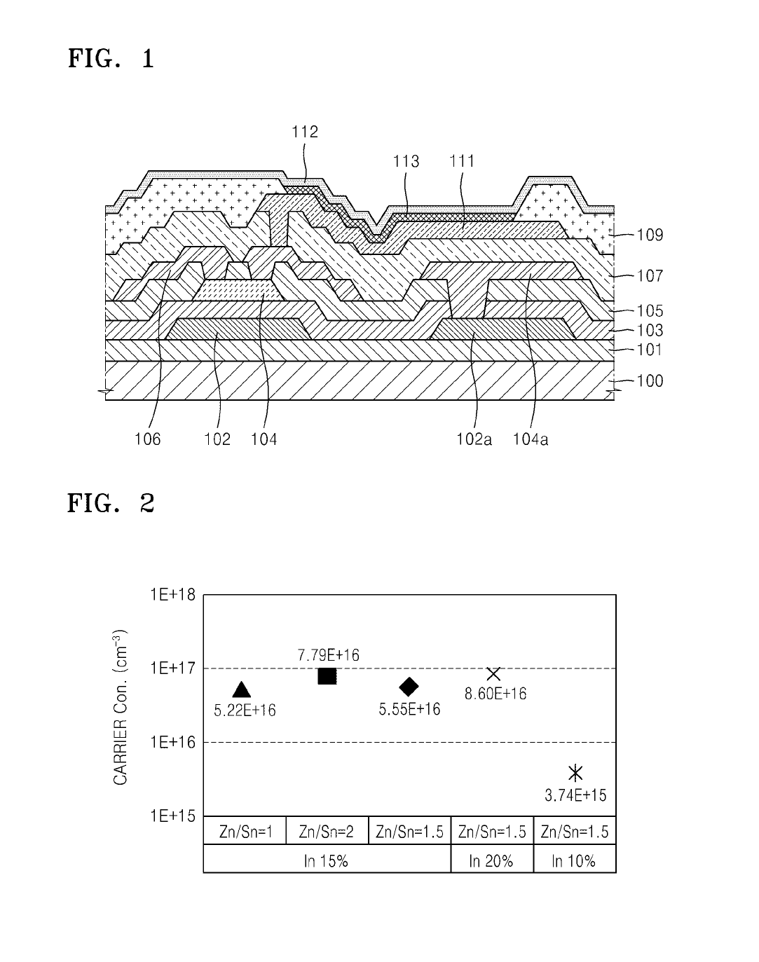

FIG. 1 is a cross-sectional view schematically illustrating an organic light-emitting display apparatus including a thin film transistor in accordance with an exemplary embodiment of the present invention.

A base substrate 100 may be formed by using various materials such as a glass material, a metal material or a plastic material. On the base substrate 100, a buffer layer 101 formed by using silicon oxide, silicon nitride, or the like may be disposed to planarize the surface of the base substrate 100 or to prevent the penetration of impurities, etc. into the thin film transistor.

On the buffer layer 101, a thin film transistor array is provided. The thin film transistor array is obtained by arranging a plurality of thin film transistors. Each of the thin film transistors includes a gate electrode 102, a semiconductor layer 104, and source/drain electrodes 106.

On the buffer layer 101, the gate electrode 102 is provided. According to a signal applied into the gate electrode 102, the source/drain electrodes 106 may electrically communicate with a data line which transmits data signal. The gate electrode 102 may be formed by using at least one material among aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W) and copper (Cu). The material of the gate electrode 102 is selected considering an adhesion properties with an adjacent layer, a surface planarization degree and an ease of a process of the layer. The gate electrode 102 may be formed as a single layer or a multi-layer. The gate electrode 102 may be formed by depositing the gate electrode material on the buffer layer by means of an evaporation method, a vaporization method or a sputtering method, and patterning using a conventional photolithography process. While forming the gate electrode 102, a gate line 102a may be formed at the same time using the same layer and the same material as the gate electrode 102.

The semiconductor layer 104 includes an oxide semiconductor material. According to an exemplary embodiment of the present invention, the semiconductor layer 104 may include about 5-25 atom % of gallium, about 10-40 atom % of indium, tin and zinc. Wherein, zinc and tin may include by zinc:tin=1:5. The ITZO including indium (In) in an amount of about 10 atom % to about 40 atom % with respect to the semiconductor layer has high mobility of about 30 cm²/V·sec or above, for example, about 30 cm²/V·sec to about 60 cm²/V·sec. Generally, gallium indium tin oxide (GIZO) has a lower mobility of about 10 cm²/V·sec or less. Using the ITZO as the semiconductor layer, a high resolution organic light-emitting display apparatus such as an ultra high definition (UHD) display may be manufactured because of its high mobility.

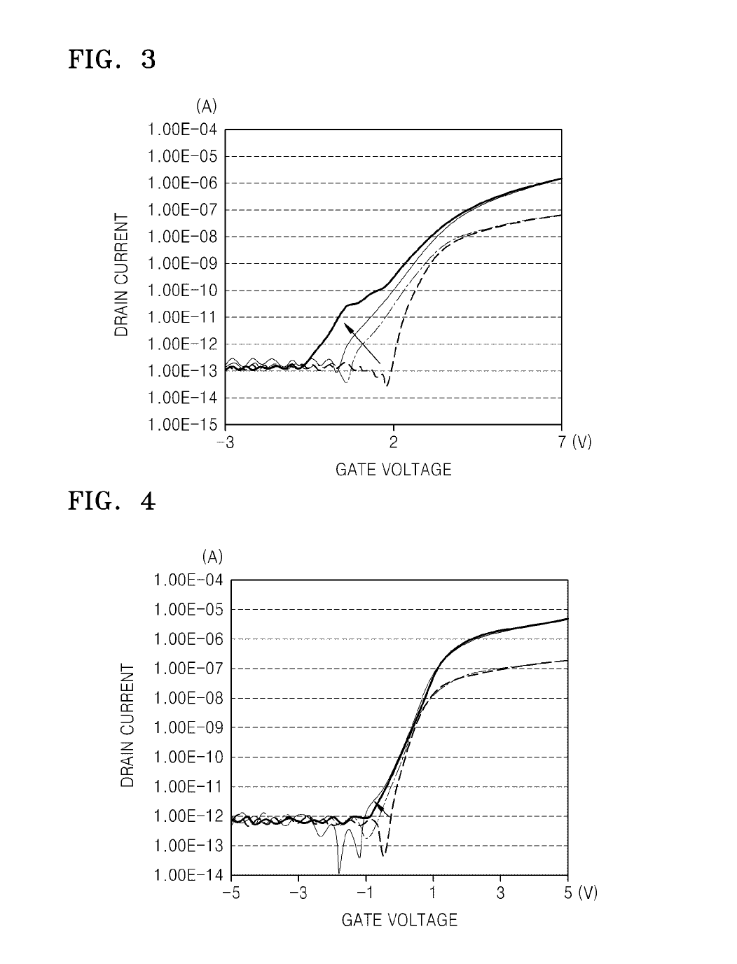

FIG. 2 is a graph illustrating carrier properties according to the concentration of indium (atom %) included in a semiconductor layer 104. The carrier concentration is decreased when the indium concentration is decreased from 20 atom % to 10 atom %. According to the experimental results, the high mobility may not be achieved when decreasing indium concentration.

Generally, when the indium concentration exceeds about 40 atom %, the thin film transistor may be sensitive to light, and may have bad light reliability. Detailed description with respect to the light reliability will be given herein below.

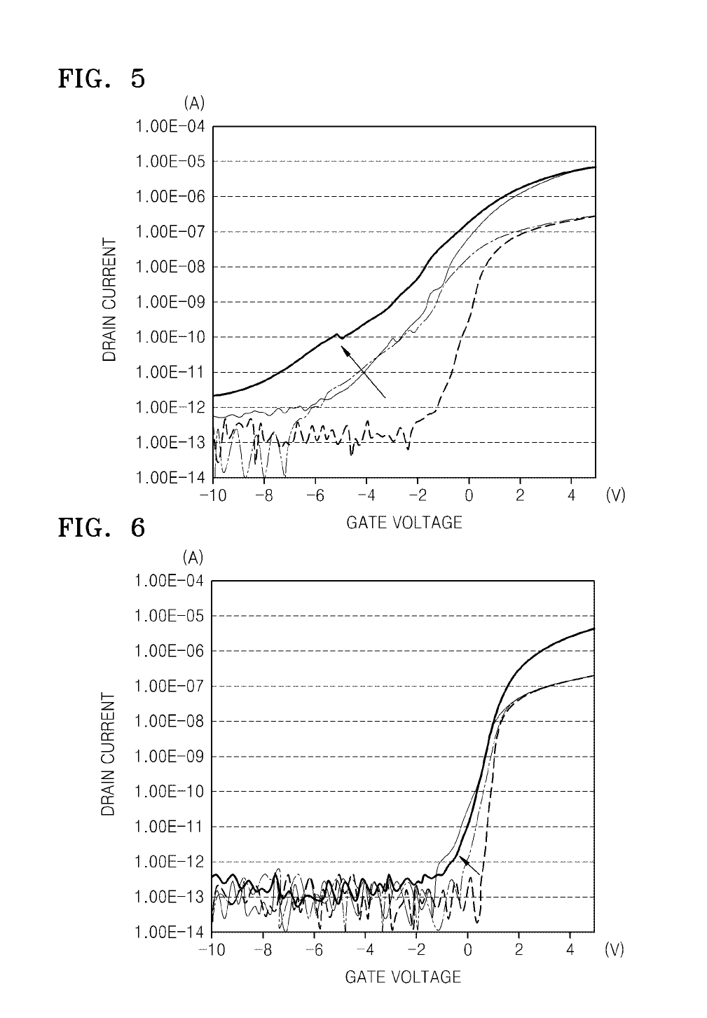

The semiconductor layer 104 formed by using the ITZO has a bad reliability. FIG. 3 is a graph illustrating properties of a transistor using ITZO as a semiconductor layer, in which drain current intensity according to gate voltage is shown for a thin film transistor formed by using the ITZO having about 10 atom % of indium. Referring to the transistor in FIG. 3, the change in threshold voltage, the value of the gate-source voltage when the channel starts to allow current flow between a source and a drain of the transistor, is observed to be sensitive to light intensity. The graph of a dotted line represents drain current intensity according to gate voltage when the intensity of the environmental light is several tens of lux, and the graph of a bold solid line represents drain current intensity according to gate voltage when the intensity of the environmental light is several thousands of lux. In addition, the threshold voltage may be severely changed according to the change in intensity of light, as indicated by an arrow. Thus, the light sensitivity of the thin film transistor of FIG. 3 is high.

When the semiconductor layer 104 is manufactured using a target including gallium, Indium, Tin and Zinc oxides, the high mobility and the high light reliability of materials may be obtained. The gallium may be included in a range of about 5 atom % to about 25 atom % with respect to the semiconductor layer. When the amount of gallium included in the semiconductor layer is about 5 atom % or less, a similar graph as in FIG. 3A may be obtained, and the light sensitivity of the thin film transistor may be high. When the amount of gallium included in the semiconductor layer is about 25 atom % or above, a graph as illustrated in FIG. 4 may be obtained.

FIG. 4 is a graph illustrating properties of a transistor, in which drain current intensity according to a gate voltage is shown for a thin film transistor formed by using the semiconductor layer having about 10 atom % of indium, and about 5 atom % of gallium. Referring to the transistor of FIG. 4, the change in threshold voltage is observed to be insensitive to light intensity. The graph of a dotted line represents drain current intensity according to gate voltage when the intensity of the environmental light is several tens of lux, and the graph of a bold solid line represents drain current intensity according to gate voltage when the intensity of the environmental light is several thousands of lux. In addition, the threshold voltage may be almost unchanged according to the change in intensity of light, as indicated by an arrow. Thus, the light sensitivity of the thin film transistor of FIG. 4 is low, and the light reliability of materials is good.

FIG. 5 is a graph illustrating properties of a transistor, in which drain current intensity according to gate voltage is shown for a thin film transistor formed by using the ITZO having about 40 atom % of indium. Referring to the transistor of FIG. 5, the change in threshold voltage is observed to be sensitive to light intensity. The graph of a dotted line represents drain current intensity according to gate voltage when the intensity of the environmental light is several tens of lux, and the graph of a bold solid line represents drain current intensity according to gate voltage when the intensity of the environmental light is several thousands of lux. In addition, the threshold voltage may be severely changed according to the change in intensity of light, as indicated by an arrow. Thus, the light sensitivity of the thin film transistor of FIG. 5 is high.

FIG. 6 is a graph illustrating properties of a transistor, in which drain current intensity according to gate voltage is shown for a thin film transistor formed by using the semiconductor layer having about 5 atom % of gallium, about 40 atom % of indium,. Referring to the transistor of FIG. 6, the change in threshold voltage is observed to be insensitive to light intensity. The graph of a dotted line represents drain current intensity according to gate voltage when the intensity of the environmental light is several tens of lux, and the graph of a bold solid line represents drain current intensity according to gate voltage when the intensity of the environmental light is several thousands of lux. In addition, the threshold voltage may be almost unchanged according to the change in intensity of light, as indicated by an arrow. Thus, the light sensitivity of the thin film transistor of FIG. 6 is low, and the reliability of materials is high. Therefore, the addition of 5 atom % of gallium to the semiconductor layer having Indium, zinc and Tin corresponds to a critical value confirming the reliability of materials of the thin film transistor.

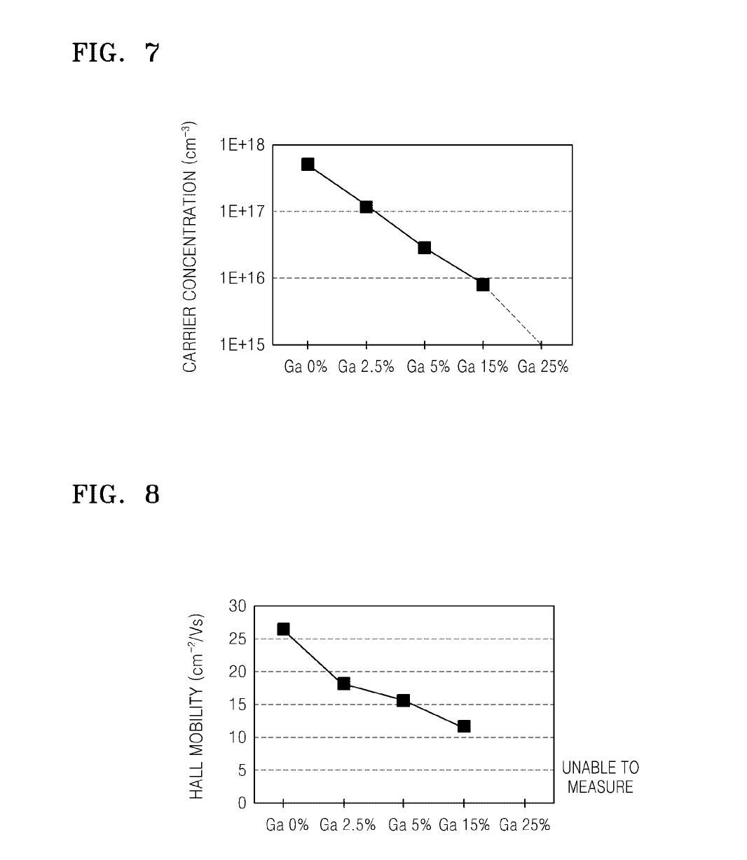

The preferable amount of the gallium included in the semiconductor layer 104 is about 25 atom % or less because carrier concentration of the thin film transistor is inverse proportional to the concentration of gallium. As illustrated in FIGS. 7 and 8, when the amount of the gallium exceeds about 25 atom % with respect to the semiconductor layer 104, the carrier concentration is decreased to about 1E+14 cm⁻³. Hall mobility could not be measured. Thus, 25 atom % corresponds to a critical value for operating the thin film transistor.

When forming the semiconductor layer 104, a semiconductor material is sputtered on the gate insulating layer 103b using a single target including gallium indium tin zinc oxide (GITZO). Then, the semiconductor material is patterned by a photolithography process to form the semiconductor layer 104.

A gate insulating layer 103 is formed between the gate electrode 102 and the semiconductor layer 104 to provide insulation therebetween. After forming a gate insulating layer 103 to cover the gate electrode 102, the semiconductor layer 104 is formed on the gate insulating layer 103. The gate insulating layer 103 may be a single layer of silicon oxide. However, the gate insulating layer 103 is not limited thereto, and may be a stacked layer of silicon oxide/silicon nitride/silicon oxide.

An etch stopping layer material is formed to cover the semiconductor layer 104 on the semiconductor layer 104, and a contact hole exposing a portion of the semiconductor layer 104 is formed. An etch stopping layer 105 may be a single layer of silicon oxide. However, the etch stopping layer 105 is not limited thereto, and may be a stacked layer of silicon oxide/silicon nitride/silicon oxide.

When hydrogen ions penetrate into the oxide semiconductor layer 104, the carrier concentration of the oxide semiconductor layer 104 may be increased to exhibit conductivity. Thus, the threshold voltage may be shifted and the thin film transistor may not be suitable to be used as a switch for display device. Generally, the amount of hydrogen in silicon oxide is smaller than that in silicon nitride. When the gate insulating layer 103 and the etch stopping layer 105 making a direct contact with the semiconductor layer 104 are formed using silicon oxide, reliability of a transistor may be improved.

Source/drain electrode materials are formed on the contact hole and the etch stopping layer 105. The Source/drain electrode materials are patterned by a photolithography process to form source/drain electrodes 106. The source/drain electrodes 106 may be formed by using at least one material among aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W) and copper (Cu), or the like in consideration of the conductivity. The source/drain electrodes 106 may be formed as a single layer or a multi-layer. While forming the source/drain electrodes 106, a data line 106a may be formed at the same time, on the same layer, and by using the same material as the source/drain electrodes 106.

A bottom gate type may be applied to the thin film transistor in accordance with an exemplary embodiment of the inventive concept. Since the semiconductor layer of the thin film transistor has high mobility, a high temperature treatment after forming the semiconductor is not preferable. Thus, the gate insulating layer 103 deposited at a high temperature may be formed before the semiconductor layer 104 is formed. In this case, the generation of a short circuit between the semiconductor layer and gate electrode due to high temperature damage that results during the forming of the gate insulating layer 103 may be prevented.

A passivation layer 107 covering the thin film transistor may be formed. The passivation layer 107 may be formed by using an inorganic material such as silicon oxide, silicon nitride, silicon oxynitride, or the like, or may be formed by using an acryl organic material, benzocyclobutene (BCB), or the like. Referring to FIG. 1, the passivation layer 107 is illustrated as a single layer, however various structures including a multi-layer structure may be formed.

On the passivation layer 107, an organic light-emitting device (OLED) including a pixel electrode 111, an opposite electrode 112 and an intermediate layer 113 including a light-emitting layer between the pixel electrode 111 and the opposite electrode 112, is disposed.

In the passivation layer 107, an opening portion exposing a portion of one of source/drain electrodes 106 of a thin film transistor is provided. The pixel electrode 111 is electrically connected to the thin film transistor by making contact with one of the source/drain electrodes 106 through the opening portion, and is disposed on the passivation layer 107. The pixel electrode 111 may be formed as a (semi)transparent electrode or a reflection type electrode. The (semi)transparent electrode may be formed by using, for example, ITO, IZO, ZnO, In₂O₃, IGO or AZO. The reflection type electrode may include a reflection layer formed by using Ag, Mg, Al, Pt, Pd, Au, Ni, Nd, Ir, Or or a compound thereof, and a layer formed by using ITO, IZO, ZnO, In₂O₃, IGO or AZO. Of course, the present invention is not limited thereto, and various materials may be applied. The structure may also include various shapes including a single layer, a multi-layer, or the like.

On the passivation layer 107, a pixel defining layer 109 may be disposed. The pixel defining layer 109 defines a pixel by including an opening corresponding to each of the pixels, that is, an opening exposing at least the center portion of the pixel electrode 111. The pixel defining layer 109 may prevent the generation of an arc at the terminal of the pixel electrode 111 by increasing the distance between the terminal of the pixel electrode 111 and the opposite electrode 112 at the upper portion of the pixel electrode 111. The pixel defining layer 109 may be formed by using an organic material such as polyimide.

The intermediate layer 113 of the OLED may include a low molecular weight material or a high molecular weight material. When the low molecular weight material is used, a hole injection layer (HIL), a hole transport layer (HTL), an emission layer (EML), an electron transport layer (ETL), an electron injection layer (EIL), or the like may be formed as a single layer or by stacking into a complex structure. Various organic materials including copper phthalocyanine (CuPc), N,N-di(naphthalene-1-yl)-N,N′-diphenyl-benzidine (NPB), tris-8-hydroxyquiloline aluminum (Alq3), or the like may be used. The layers may be formed by a vacuum deposition method.

When the intermediate layer 113 includes the high molecular weight material, the intermediate layer 113 may have a structure including the HTL and the EML. In this case, PEDOT may be used as the HTL, and a high molecular weight material such as poly-phenylenevinylene (PPV)-based compound and polyfluorene-based compound may be used as the EML. The layers may be formed by means of a screen printing method, an inkjet printing method, a laser induced thermal imaging (LITI) method, or the like.

Of course, the intermediate layer 113 is not limited thereto, and may include various structures.

The opposite electrode 112 may be disposed to cover the entire substrate. The opposite electrode 112 may be formed as one body on a plurality of OLEDs to correspond to a plurality of pixel electrodes 111. The opposite electrode 112 may be formed as a (semi)transparent electrode or a reflection type electrode. When the opposite electrode 112 is formed as the (semi)transparent electrode, a layer formed by using a metal having a low work function such as Li, Ca, LiF/Ca, LiF/Al, Al, Ag, Mg and a compound thereof, and a (semi)transparent conductive layer such as ITO, IZO, ZnO or In₂O₃ may be included. When the opposite electrode 112 is formed as the reflection type electrode, a layer formed by using Li, Ca, LiF/Ca, LiF/Al, Al, Ag, Mg and a compound thereof may be included. Of course, the constitution and the material of the opposite electrode 112 are not limited thereto, and various modifications may be possible.

It should be understood that the exemplary embodiments described therein should be considered in a descriptive purpose only and not for purposes of limitation of the invention. Descriptions of features or aspects within each embodiment should typically be considered as available for other similar features or aspects in other embodiments.

While one or more embodiments of the present invention have been described with reference to the figures, it will be understood by those of ordinary skill in the art that various changes in form and details may be made therein without departing from the spirit and scope of the present invention as defined by the following claims.

What is claimed is:

1. A thin film transistor comprising:
a gate electrode provided on a substrate;
a semiconductor layer insulated from the gate electrode, and including gallium, indium, tin and zinc oxide); and
source/drain electrodes formed on the semiconductor layer.

2. The thin film transistor of claim 1, wherein an amount of the gallium is from about 5 atom % to about 25 atom % of the semiconductor layer.

3. The thin film transistor of claim 2, wherein an amount of indium is from about 10 atom % to about 40 atom % of the semiconductor layer.

4. The thin film transistor of claim 1, further comprising:
a gate insulating layer interposed between the gate electrode and the semiconductor layer and making contact with the gate electrode and the semiconductor layer; and
an etch stopping layer interposed between the semiconductor layer and the source/drain electrodes and making contact with the semiconductor layer and the source/drain electrodes,
the gate insulating layer and the etch stopping layer including silicon oxide.

5. An organic light-emitting display apparatus, comprising:
a thin film transistor comprising a gate electrode provided on a substrate;
a semiconductor layer insulated from the gate electrode, and including gallium, indium, tin and zinc oxide; and source/drain electrodes formed on the semiconductor layer;
a passivation layer covering the thin film transistor; and
an organic light-emitting device provided on the passivation layer and including a first electrode, an intermediate layer and a second electrode.

6. The organic light-emitting display apparatus of claim 5, wherein an amount of the gallium is from about 5 atom % to about 25 atom % of the semiconductor layer.

7. The organic light-emitting display apparatus of claim 6, wherein an amount of indium (In) is from about 10 atom % to about 40 atom % of the semiconductor layer.

8. The organic light-emitting display apparatus of claim 5, further comprising:
a gate insulating layer interposed between the gate electrode and the semiconductor layer and making contact with the gate electrode and the semiconductor layer; and
an etch stopping layer interposed between the semiconductor layer and the source/drain electrodes and making contact with the semiconductor layer and the source/drain electrodes,
the gate insulating layer and the etch stopping layer including silicon oxide (SiOx).

9. A method of manufacturing a thin film transistor, the method comprising:
depositing a gate electrode material on a substrate and patterning the gate electrode material to form a gate electrode;
depositing, by using a single target including gallium indium tin zinc oxide (GITZO), a semiconductor material on the gate electrode, the semiconductor material insulated from the gate electrode, and patterning the semiconductor material to form a semiconductor layer; and
depositing source/drain materials on the semiconductor layer and patterning the deposited source/drain materials to form source/drain electrodes to make contact with the semiconductor layer through a contact hole.

10. The method of claim 9, wherein an amount of gallium is from about 5 atom % to about 25 atom % of the semiconductor layer.

11. The method of claim 10, wherein an amount of indium (In) is from about 10 atom % to about 40 atom % of the semiconductor layer.

12. The method of claim 9, further comprising:
forming a gate insulating layer to cover the gate electrode; and
depositing an etch stopping material to cover the semiconductor layer and patterning to form the contact hole,
the gate insulating layer and the etch stopping layer including silicon oxide (SiOx).

13. The method of claim 9, wherein the depositing a semiconductor material is performed by a sputtering method.

14. The method of claim 13, wherein an amount of gallium is from about 5 atom % to about 25 atom % of the semiconductor layer.

15. The method of claim 14, wherein an amount of indium (In) is from about 10 atom % to about 40 atom % of the semiconductor layer.
